(19) United States
(12) Patent Application Publication
(10) Pub. No.: US 2024/0387480 A1
(43) Pub. Date: Nov. 21, 2024

(54) METHOD FOR MANUFACTURING SUBSTRATE AND METHOD FOR MANUFACTURING LIGHT-EMITTING DEVICE

(71) Applicant: NICHIA CORPORATION, Anan-shi (JP)

(72) Inventor: Yoichi BANDO, Anan-shi (JP)

(21) Appl. No.: 18/663,022

(22) Filed: May 13, 2024

(30) Foreign Application Priority Data
May 17, 2023 (JP) 2023-081742

(51) Int. Cl. H01L 25/075

(52) U.S. Cl. CPC H01L 25/0753; H01L 2933/005

(57) ABSTRACT

A method for manufacturing a substrate includes: preparing a substrate intermediate including a plurality of bases each having an upper surface and an outer lateral surface, and a support member supporting the bases such that the outer lateral surfaces of the bases are spaced apart from each other; preparing a plate-shaped member defining a plurality of openings; disposing the plate-shaped member on the support member such that at least a portion of an inner lateral surface of each of the openings and at least a portion of the outer lateral surface of a corresponding one of the bases face each other via a gap; supplying a resin member to the gap such that the resin member covers the outer lateral surface of each of the bases; and curing the resin member to form a covering layer covering the outer lateral surface of each of the bases.

### CROSS-REFERENCE TO RELATED APPLICATIONS

This application claims priority to Japanese Patent Application No. 2023-081742 filed on May 17, 2023, the disclosure of which is hereby incorporated by reference in its entirety.

### TECHNICAL FIELD

The present disclosure relates to a method for manufacturing a substrate and a method for manufacturing a light-emitting device.

### BACKGROUND ART

Coloring the upper and lateral surfaces of a package molded body in black using a screen printing method has been known (Japanese Patent Publication No. JP 2010-093185 A).

### SUMMARY

It is an object of an embodiment of the present disclosure to provide a method for applying a resin member to a lateral surface of a base.

The present disclosure includes the following configurations.
A method for manufacturing a substrate includes: preparing a substrate intermediate including a plurality of bases each having an upper surface and an outer lateral surface continuous with the upper surface, and a support member supporting the bases such that the outer lateral surfaces of the bases are spaced apart from each other; preparing a plate-shaped member defining a plurality of openings; disposing the plate-shaped member on the support member such that at least a portion of an inner lateral surface of each of the openings of the plate-shaped member and at least a portion of the outer lateral surface of a corresponding one of the bases face each other via a gap; supplying a resin member to the gap such that the resin member covers the outer lateral surface of each of the bases; and curing the resin member to form a covering layer covering the outer lateral surface of each of the bases.
A method for manufacturing a light-emitting device includes: preparing an intermediate member including a plurality of light-emitting device intermediates each including a plurality of bases each having an upper surface and an outer lateral surface continuous with the upper surface, and a plurality of light-emitting elements held on the bases, and a support member supporting the light-emitting device intermediates such that the outer lateral surfaces of the bases are spaced apart from each other; preparing a plate-shaped member defining a plurality of openings; disposing the plate-shaped member on the support member such that at least a portion of an inner lateral surface of each of the openings of the plate-shaped member and at least a portion of the outer lateral surface of a corresponding one of the bases face each other via a gap; supplying a resin member to the gap such that the resin member covers the outer lateral surface of each of the bases; and curing the resin member to form a covering layer covering the outer lateral surface of each of the bases.

According to an embodiment of the present disclosure, the method for disposing the resin member on the lateral surface of the base can be provided.

### BRIEF DESCRIPTION OF DRAWINGS

FIG. 1A illustrates a schematic top view and two schematic side views of a substrate obtained by a method for manufacturing a substrate according to an embodiment.

FIG. 1B is an enlarged schematic top view of a portion including a base illustrated in FIG. 1A.

FIG. 1C is an enlarged schematic side view of a portion including the base illustrated in FIG. 1A.

FIG. 1D is a schematic cross-sectional view of line ID-ID of FIG. 1B.

FIG. 2A illustrates a schematic top view and two schematic side views of a substrate intermediate according to the embodiment.

FIG. 2B is an enlarged schematic top view of a portion including the base illustrated in FIG. 2A.

FIG. 2C is a schematic top view in which a support member illustrated in FIG. 2B is clearly indicated.

FIG. 2D is an enlarged schematic side view of a portion including the base illustrated in FIG. 2A.

FIG. 3A is a schematic view illustrating a method for manufacturing the substrate according to the embodiment.

FIG. 3B is a schematic view illustrating the method for manufacturing the substrate according to the embodiment.

FIG. 3C is a schematic view illustrating the method for manufacturing the substrate according to the embodiment.

FIG. 4A is a schematic view illustrating the method for manufacturing the substrate according to the embodiment.

FIG. 4B is a schematic view illustrating the method for manufacturing the substrate according to the embodiment.

FIG. 4C is a schematic view illustrating the method for manufacturing the substrate according to the embodiment.

FIG. 4D is a schematic view illustrating the method for manufacturing the substrate according to the embodiment.

FIG. 4E is a schematic view illustrating the method for manufacturing the substrate according to the embodiment.

FIG. 5A is a schematic view illustrating the method for manufacturing the substrate according to the embodiment.

FIG. 5B is a schematic view illustrating the method for manufacturing the substrate according to the embodiment.

FIG. 5C is a schematic view illustrating the method for manufacturing the substrate according to the embodiment.

FIG. 6 is an enlarged schematic cross-sectional view of a portion of the substrate obtained by the method for manufacturing the substrate according to the embodiment.

FIG. 7A is a schematic view illustrating the method for manufacturing the substrate according to the embodiment.

FIG. 7B is a schematic view illustrating the method for manufacturing the substrate according to the embodiment.

FIG. 8A illustrates a schematic top view and two schematic side views obtained by a method for manufacturing a substrate according to an embodiment.

FIG. 8B is an enlarged schematic top view of a portion including a base illustrated in FIG. 8A.

FIG. 8C is a schematic cross-sectional view of line VIIIC-VIIIC of FIG. 8B.

FIG. 8D illustrates a schematic top view and two schematic side views of a substrate intermediate according to the embodiment.

FIG. 9A is a schematic top view of a light-emitting device obtained by a method for manufacturing a light-emitting device according to an embodiment.

FIG. 9B is a schematic side view of the light-emitting device obtained by the method for manufacturing the light-emitting device according to the embodiment.

FIG. 9C is a schematic cross-sectional view of line IXC-IXC of FIG. 9A.

FIG. 10 is a schematic top view of the light-emitting device obtained by the method for manufacturing the light-emitting device according to the embodiment.

FIG. 11A illustrates a schematic top view and two schematic side views of the light-emitting device obtained by the method for manufacturing the light-emitting device according to the embodiment.

FIG. 11B is a schematic cross-sectional view of line XIB-XIB of FIG. 11A.

FIG. 12A illustrates a schematic top view and two schematic side views of the light-emitting device obtained by the method for manufacturing the light-emitting device according to the embodiment.

FIG. 12B is a schematic cross-sectional view of line XIIB-XIIB of FIG. 12A.

FIG. 12C is a schematic cross-sectional view of line XIIC-XIIC of FIG. 12A.

### DESCRIPTION OF EMBODIMENTS

Embodiments of the present invention will be described below with reference to the attached drawings. The following embodiments are provided as examples and do not limit a method for manufacturing a substrate and a method for manufacturing a light-emitting device according to the embodiments of the present invention. For example, the numerical values, shapes, materials, steps, and the order of the steps illustrated in the following embodiments are only exemplary, and various alterations are possible as long as no technical inconsistencies occur. The embodiments described below can be combined in various ways as long as no technical inconsistencies occur.

In the drawing, the dimensions, shapes, and the like of the constituent components illustrated therein may be exaggerated for clarity, and do not reflect actual dimensions, shapes, and size relationships among the constituent components, in some cases. Furthermore, in order to avoid excessive complexity in the drawings, schematic views that omit some elements may be used, or end views that illustrate only cut surfaces may be used as cross-sectional views.

### First Embodiment

A substrate obtained by a method for manufacturing a substrate according to the present embodiment includes a plurality of bases and a support member supporting the bases such that outer lateral surfaces of the plurality of bases are disposed at a distance from each other. Each of the bases has an upper surface and lateral surfaces, and a covering layer is disposed on the lateral surfaces.

The base is a member capable of being a part of a package included in a light-emitting device. That is, the substrate obtained in the present embodiment is a member that can be used in a method for manufacturing a light-emitting device, which will be described later.

The following methods may be used to manufacture such a substrate.

One method is to use a member constituting a part of the package of the light-emitting device, as the support member (substrate manufacturing method 1). Another method is to use a member which is not a constituent part of the package of the light-emitting device, as the support member (substrate manufacturing method 2).

In either case, the method for manufacturing the substrate includes the following steps:
(1-1) Step of preparing a substrate intermediate including a base and a support member supporting the base
(1-2) Step of preparing a plate-shaped member having an opening
(1-3) Step of disposing the plate-shaped member on the support member so as to dispose the base in the opening of the plate-shaped member
(1-4) Step of supplying a resin member to a gap between the lateral surface of the base and the plate-shaped member such that it covers an outer lateral surface of the base
(1-5) Step of curing the resin member to form a covering layer covering the lateral surface of the base

### Substrate Manufacturing Method 1

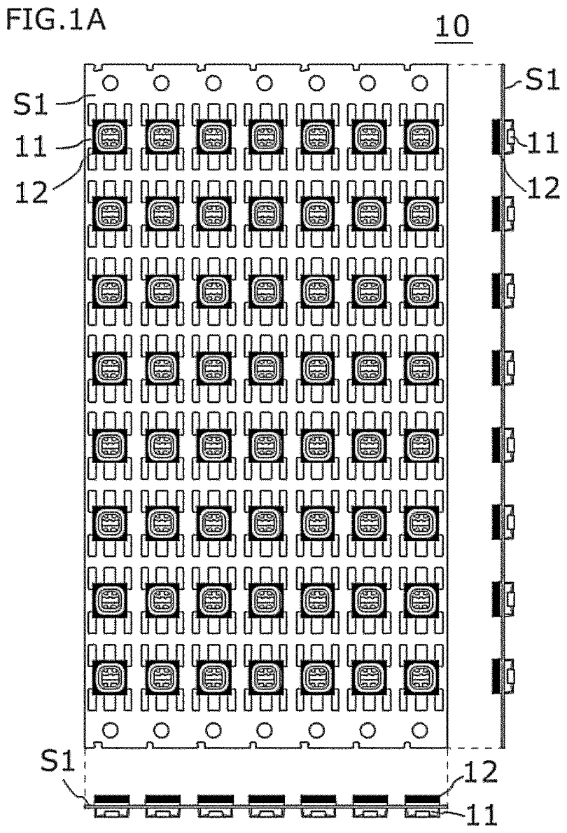

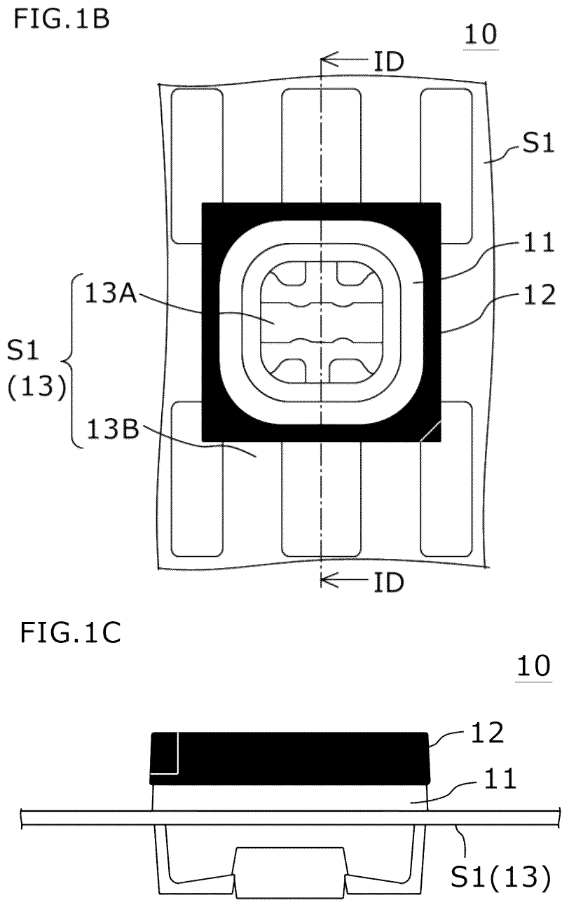

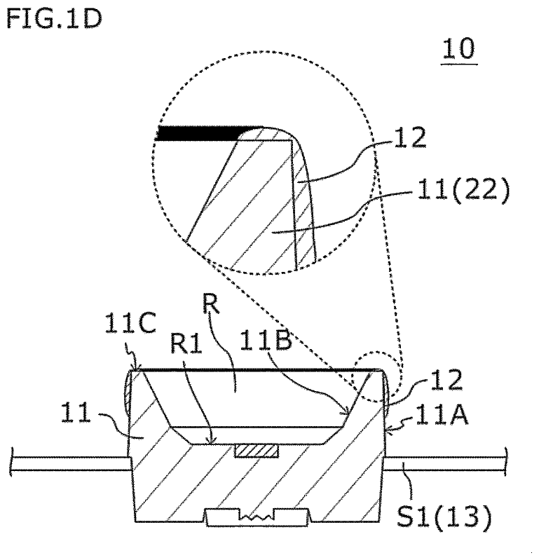

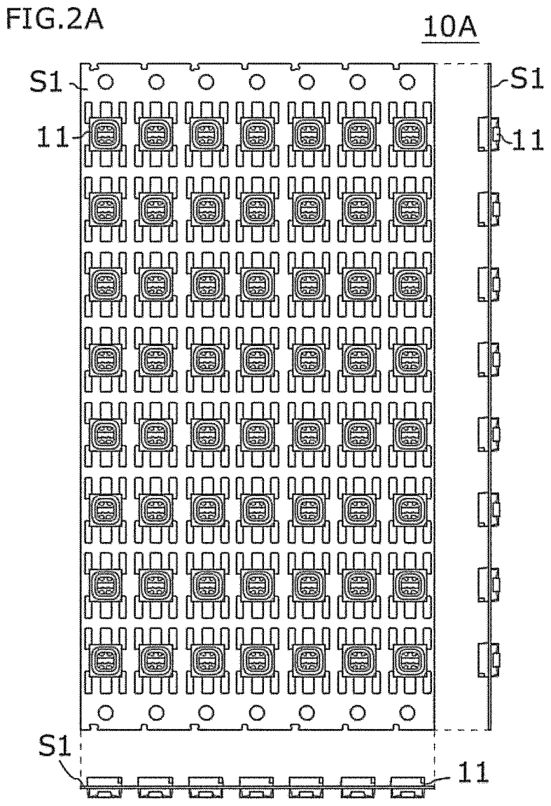

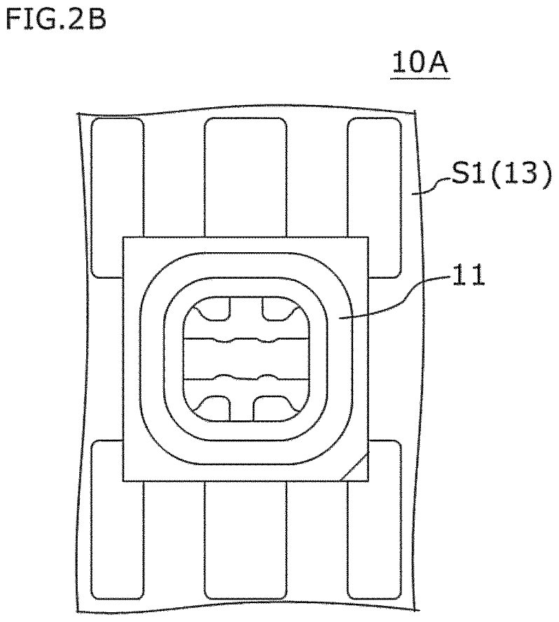

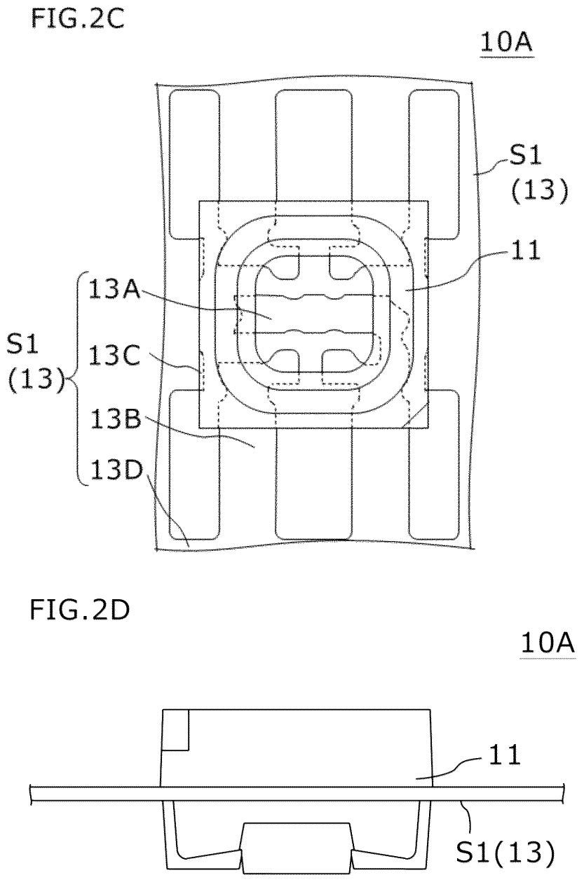

FIG. 1A illustrates a top view and two side views of a substrate 10 obtained by a method for manufacturing the substrate according to the present embodiment. FIG. 1B is an enlarged top view of a portion including one base 11 of the substrate 10 illustrated in FIG. 1A. FIG. 1C is an enlarged side view of a portion including one base 11 of the substrate 10 illustrated in FIG. 1A. FIG. 1D is a cross-sectional view of line ID-ID of FIG. 1B. FIG. 2A illustrates a top view and two side views of a substrate intermediate 10A used in the method for manufacturing the substrate according to the present embodiment. FIG. 2B is an enlarged top view of a portion including one base 11 of the substrate intermediate 10A illustrated in FIG. 2A. FIG. 2C is a top view in which a support member S1 (conductive member 13) in a portion buried in the base 11 of the substrate intermediate 10A illustrated in FIG. 2B is clearly indicated. FIG. 2D is an enlarged side view of a portion including one base 11 of the substrate intermediate 10A illustrated in FIG. 2A.

The substrate 10 includes a base 11, a covering layer 12 disposed on the base 11, and a support member S1. The substrate 10 includes one support member S1 and a plurality of bases 11. In the example illustrated in FIG. 1A, a total of 56 (7×8) bases 11 are supported by one support member S1, with the bases 11 being arranged at equal intervals in the vertical and lateral directions. The covering layer 12 is disposed on an outer lateral surface 11A of each of the bases 11. In the example illustrated in FIG. 1A and the like, the covering layer 12 is also disposed on an upper surface 11C of the base 11. The number of the bases 11, the interval at which the bases 11 are arranged, and the like can be selected optionally. The interval at which the bases 11 are arranged can be, for example, in a range from 1 mm to 5 mm.

The support member S1 is a conductive member or a composite member including a conductive member. When the support member S1 is made of only a conductive member, for example, a lead frame can be used. As the composite member including the conductive member, a rigid or flexible substrate including an insulating base material and a conductive wiring layer can be used.

A shape of the support member S1 may be, for example, square or rectangular in a top view. The size of the support member S1 is, for example, in a range from 15 mm to 250 mm in length on the short side, in a range from 15 mm to 250 mm in length on the long side, and in a range from 50 μm to 1000 μm in thickness. Examples of the conductive material of the support member S1 include metal materials such as Fe, Cu, Ni, Al, Ag, Au, and an alloy containing one of these metals. The support member S1 can include a plating layer on the surface of any of the metal materials mentioned above. The plating layer may contain, for example, Au, Ag, Cu, Pt, Ni, or an alloy containing one of these metals, and may be provided in a single layer structure or a multiple layer structure. When the support member S1 is the rigid substrate, the base material may be made of a ceramic such as aluminum nitride or aluminum oxide, a glass epoxy substrate (FR-4), a glass composite substrate (SEM3), a bismaleimide-triazine resin (BT-resin), or paper epoxy. When the support member S1 is the flexible substrate, the support member S1 includes a film-like insulating body (resin) and a conductor wiring layer formed using, for example, copper. Examples of the resin material constituting the insulating body include a phenol resin, an epoxy resin, a polyimide resin, a BT resin, polyphthalamide (PPA), polyethylene terephthalate (PET), and the like.

The substrate 10 illustrated in FIG. 1A includes a lead frame which is the conductive member 13, as the support member S1.

As illustrated in FIG. 2C, the conductive member (lead frame) 13 used as the support member S1 includes an inner lead 13A disposed on an inner side relative to the outer lateral surface 11A and at least partially buried in the base 11, and an outer lead 13B disposed protruding outward from the outer lateral surface 11A of the base 11. The inner lead 13A and the outer lead 13B constitute a part of the package constituting the light-emitting device. A suspended lead 13C disposed on the outer lateral surface 11A different from the one for the outer lead 13B is slightly buried in the outer lateral surface 11A of the base 11. In addition, a frame portion 13D is provided connecting the outer lead 13B and the suspended lead 13C. The suspended lead 13C supports the base 11 after the frame portion 13D and the outer lead 13B are cut. In the substrate 10 illustrated in FIG. 1A, the outer lead 13B and the frame portion 13D are continuous. However, the substrate 10 may be in a state in which the outer lead 13B and the frame portion 13D are cut, or a state in which the outer lead 13B is bent after the outer lead 13B and the frame portion 13D are cut. The substrate need not include the suspended lead 13C.

The base 11 is an insulating molded body included in the package for holding a light-emitting element in the light-emitting device obtained using the substrate 10. The base 11 includes an upper surface 11C and an outer lateral surface 11A continuous from the upper surface 11C. A portion of the support member S1 is buried in the base 11. In other words, the upper surface, the lateral surface, and the lower surface of a portion of the support member S1 are covered with the base 11. The support member S1 protrudes from the outer lateral surface 11A of the base 11.

The outer peripheral shape of the upper surface 11C of the base 11 is, for example, rectangular, square, circular, or the like. The size of one side of the base 11 in top view is, for example, in a range from 0.5 mm to 5 mm. The base 11 includes a recessed portion R that is open at the upper surface 11C. That is, the upper surface 11C of the base 11 is a frame-shaped portion located around the recessed portion R. The recessed portion R is a space defined by an inner lateral surface 11B and a bottom surface R1 and, in the light-emitting device, a space for disposing, for example, a light-emitting element. The inner lateral surface 11B defining the recessed portion R is composed of the base 11, and the bottom surface R1 defining the recessed portion R is composed of the base 11 and a part of the support member S1 (conductive member 13). The opening shape of the recessed portion R is, for example, rectangular, square, or circular.

In the example illustrated in FIG. 1A, the support member S1 is located near the center of the outer lateral surface 11A in the height direction of the base 11. The base 11 located above the support member S1 is thicker than the base 11 located below the support member S1. The height of the base 11 located above the support member S1 is, for example, in a range from 0.2 mm to 1.6 mm, and the height of the base 11 located below the support member S1 is, for example, in a range from 0.1 mm to 0.6 mm. However, the lower surface of the support member S1 may be positioned such that it is flush with the lower surface of the base 11.

The outer lateral surface 11A of the base 11 is inclined so as to have a wider width on the side close to the support member S1 and a narrower width on the side close to the upper surface 11C or the lower surface.

Examples of the material of the base 11 include thermoplastic resins such as polyamide (PA), polyphthalamide (PPA), polyphenylene sulfide (PPS), and liquid crystal polymer, and thermosetting resins such as an epoxy resin, a silicone resin, a modified epoxy resin, a urethane resin, and a phenol resin.

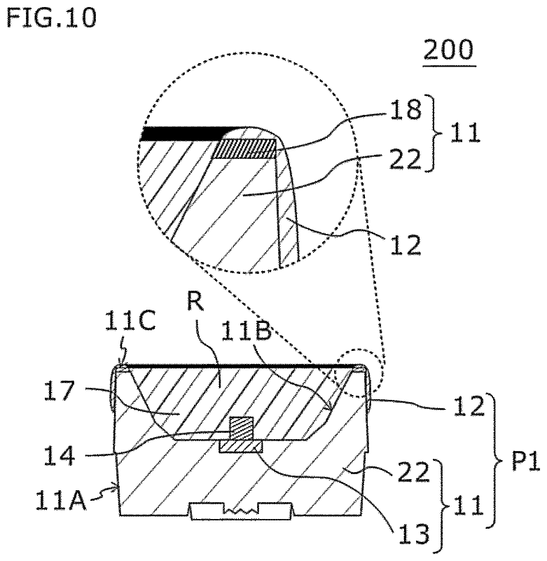

In the base 11, the outer lateral surface 11A or the upper surface 11C on which the covering layer 12 is disposed can be composed of, for example, only a molded body 22, as illustrated in FIG. 1D. Alternatively, the outer lateral surface 11A or the upper surface 11C of the base 11 on which the covering layer 12 is disposed may include the molded body 22 and a light-shielding layer 18 disposed on the upper surface of the molded body 22, as illustrated in FIG. 10.

The covering layer 12 is disposed on the outer lateral surface 11A of the base 11 and is a member having a desired function. For example, the covering layer 12 may have a function of adjusting optical characteristics. Specifically, when the substrate includes, for example, a light-absorbing layer containing a light-absorbing substance as the covering layer 12, a light-emitting device for a display capable of absorbing external light and improving the contrast ratio can be obtained. When the substrate includes a light-reflecting layer containing a light-reflecting substance as the covering layer 12, a light-emitting device capable of improving the light reflectivity of the base 11 can be obtained.

The covering layer 12 can also have a function of adjusting water resistance, light resistance, or the like. For example, providing a water-resistant layer through which moisture is unlikely to pass can improve the water resistance. When the substrate includes, as the covering layer 12, a gas barrier layer having a high gas barrier property and reducing the likelihood of passage of water vapor or a corrosive gas (a sulfur compound-containing gas such as SOx or H₂S), a light-emitting device capable of improving the gas barrier property of the base 11 can be obtained. Examples of the water-resistant layer or the gas barrier layer include an epoxy resin, a phenyl silicone resin, and the like.

When the substrate includes a light-resistant layer having high light resistance as the covering layer 12, a light-emitting device capable of improving the light resistance of the base 11 can be obtained. An example of the material of the light-resistant layer is a dimethyl silicone resin. The above-described light-absorbing substance is also a material capable of improving the light resistance of the base by absorbing light.

When a gas reactive layer that reacts with a sulfur gas or the like is provided as the covering layer 12, for example, a light-emitting device capable of improving a gas deterioration resistance of the base 11 can be obtained. Examples of the material of gas reactive particles contained in the gas reactive layer include an oxide, a hydroxide, or a carbonate of at least one element selected from potassium, calcium, sodium, magnesium, manganese, zinc, iron, copper, nickel, silver, zirconium, cobalt, chromium, lead, and barium, and a compound thereof. Specific examples thereof include a resin layer containing particles of a basic carbonate such as basic zinc carbonate (ZnCO₃·Zn(OH)₂).

The layer having any of these functions may be used as a single layer or the layers having any of these functions may be layered. One layer may have a plurality of functions.

When such a gas barrier layer or gas reactive layer is provided as the covering layer 12, the substrate capable of reducing the likelihood of deterioration of a lead frame used, which contains silver as the support member, due to a sulfur gas or the like can be obtained. Similarly, when the base 11 is a resin package including a lead containing silver or a ceramic package including a wiring line containing silver, a light-emitting device capable of reducing the likelihood of deterioration of the lead or the wiring line due to a sulfur gas can be obtained.

The covering layer 12 is disposed on the outer lateral surface 11A of the base 11. For example, the covering layer 12 can be disposed on the outer lateral surface 11A such that the outer peripheral edge of the upper surface 11C of the base 11, that is, the upper end of the outer lateral surface 11A is the upper end of the covering layer 12. However, the upper end of the covering layer 12 may be apart from the upper end of the outer lateral surface 11A. The lower end of the covering layer 12 may be disposed at a position apart from the support member S1. Alternatively, the lower end of the covering layer 12 can be disposed reaching the support member S1. For example, when the gas barrier layer, the gas reactive layer, or the like is disposed on the entire outer lateral surface 11A of the base 11, the function thereof can be easily exhibited effectively.

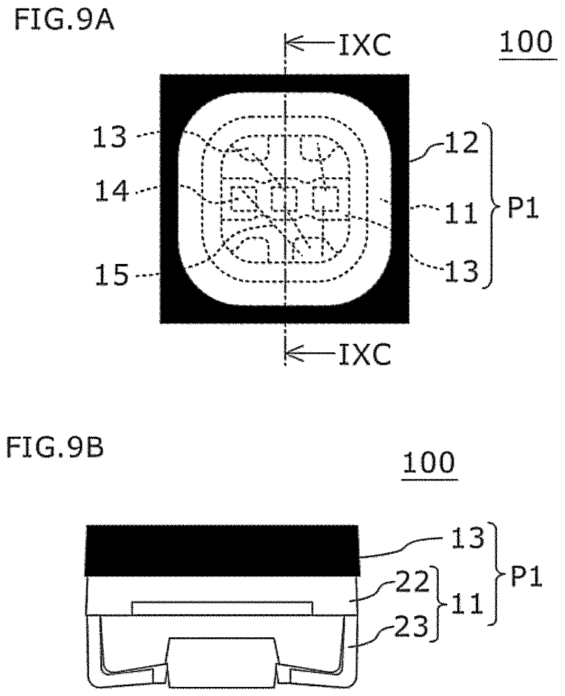

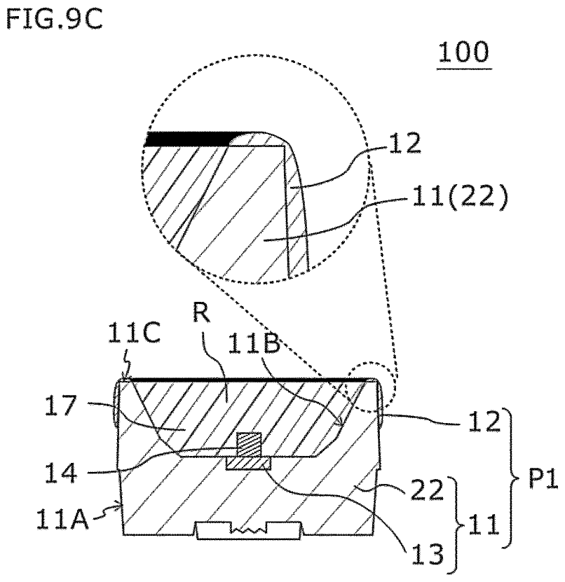

For example, when the base 11 is used as a package of the light-emitting device for a display as illustrated in FIG. 9A, a brightness of the covering layer 12 is preferably lower than a brightness of the base 11. For example, in the Munsell color system, the brightness of the covering layer 12 is preferably 1 to 6, more preferably 1 to 3, and even more preferably 1. Specifically, a dark-colored resin material such as a black resin material is preferably used for the covering layer 12. When the light-emitting device including such a covering layer 12 is mounted on a wiring board to provide a light-emitting module, a waterproof resin is provided covering around the light-emitting device. At this time, the amount of the resin member 12A to be provided is preferably adjusted such that the lateral surface of the light-emitting device exposed from the waterproof resin (the outer lateral surface 11A of the base 11) is covered with the covering layer 12. For example, of the outer lateral surface 11A of the base 11 having a height of 0.8 mm, a portion located above the support member S1 in a range with a width of 0.1 mm or more from the upper end of the outer lateral surface 11A downward can be covered with the covering layer 12. In addition, the covering layer 12 can be disposed covering down to a position at which the lower end of the covering layer 12 is apart from the support member S1 by 0.1 mm.

The lower end of the covering layer 12 may be straight parallel to the upper or lower end of the outer lateral surface 11A, or may be curved partially or entirely. As illustrated in FIG. 1C, for the covering layer 12, one covering layer 12 is preferably disposed covering a range from the left end to the right end of the outer lateral surface 11A of the base 11 in a side view. However, the covering layer 12 may be divided into two or more parts in a side view.

When the outer peripheral shape of the upper surface 11C of the base 11 is quadrangular and four outer lateral surfaces 11A are provided, the covering layer 12 is preferably disposed on all of the four outer lateral surfaces 11A. However, some of the outer lateral surfaces 11A need not be covered with the covering layer 12. When the covering layer 12 is disposed on a plurality of outer lateral surfaces 11A, the areas of the outer lateral surfaces 11A each covered with the covering layer 12 may be identical, or some or all of the areas may be different.

The covering layer 12 can be disposed not only on the outer lateral surfaces 11A of the base 11, but also on the upper surface 11C of the base 11 continuous from the outer lateral surfaces 11A. The covering layer 12 may be disposed on the upper surface 11C of the base 11 up to a position reaching the recessed portion R or at a position apart from the recessed portion R.

The thickness of the covering layer 12 can be, for example, in a range from 0.5 μm to 100 μm. In particular, the thickness of the covering layer 12 is preferably in a range from 1 μm to 30 μm. This prevents cracking of the covering layer 12 caused by expansion and contraction of the base 11 due to heating or cooling in a step of forming the light-emitting device. For example, the covering layer 12 may have a uniform thickness on one outer lateral surface 11A of the base 11. Alternatively, the thickness at the end portion of the covering layer 12 or the thickness at the end portion of the base 11 when the covering layer 12 covers the end portion of the base 11 may partially be smaller than the thickness of the other portion. In the example illustrated in FIG. 1D, the covering layer 12 covers the upper end of the outer lateral surface 11A of the base 11 in a cross-sectional view, and the thickness of that portion is thinner than that of a portion apart from the upper end. In other words, the thickness of the covering layer 12 is increased at a position apart from the upper end. Thus, for example, when a light-emitting device for a display includes the black covering layer 12, the thickness of the covering layer 12 located closer to the light-emitting element can be increased, thus further improving the contrast ratio. Such a difference in the thickness of the covering layer 12 results in a curved surface of the covering layer 12. This facilitates reflection and diffusion of external light, and improves visual recognition of the black color of the black covering layer 12.

When the covering layer 12 continuously covers the upper surface 11C and the outer lateral surface 11A of the base 11, the covering layer 12 is thinner on the side between the upper surface 11C and the outer lateral surface 11A of the base 11, that is, at a corner of the base 11 in a cross-sectional view as illustrated in FIG. 1D than at the other portion. For example, when the base 11 is white and the covering layer 12 is black, it may be difficult to recognize the boundary between the covering layer 12 disposed on the upper surface 11C and the covering layer 12 disposed on the outer lateral surface 11A in the inspection step or the like. In such a case, when the thickness of the covering layer 12 is thin at the boundary between the upper surface 11C and the outer lateral surface 11A, the white base 11 covered with the black covering layer 12 can be seen through. This facilitates the visual recognition of the outer shape of the base 11 through the covering layer 12.

The lower end of the covering layer 12 is located near the center of the outer lateral surface 11A of the base 11, and the thickness of this portion is also smaller than that of the other portion apart from the lower end. Accordingly, the covering layer 12 located at the end portion can be easily stretched, thus reducing a stress applied to the end portion due to contraction of the covering layer 12. The reduction of stress decreases the likelihood of peeling of the covering layer 12 from the end portion. The covering layer 12 disposed on the upper surface 11C of the base 11 is also thinner at the end portion of the upper surface 11C of the base 11 than at the other portion. This also decreases the likelihood of peeling of the covering layer 12 even at the end portion of the upper surface 11C.

Examples of the material of the covering layer 12 include thermosetting resins such as an epoxy resin, a modified epoxy resin, a phenol resin, a melamine resin, a (meth)acrylate resin, a urethane resin, a silicone resin, and a modified silicone resin.

The covering layer 12 may contain any of various additives such as a light-absorbing substance and a light-reflecting substance in the resin material described above. For example, the light-absorbing substance contained in the covering layer 12 is preferably a dark-colored substance such as a black or gray substance, and is specifically carbon black, titanium black, or the like. For example, the light-reflecting substance contained in the covering layer 12 is preferably a white-colored substance, specifically barium titanate, titanium oxide, aluminum oxide, silicon oxide, or the like.

Steps of the method for manufacturing the substrate as described above will be described in detail below.

### (1-1) Step of Preparing the Substrate Intermediate Including the Base and the Support Member Supporting the Base

First, a substrate intermediate 10A as illustrated in FIG. 2A is prepared. The substrate intermediate 10A is the same as the substrate 10 from which the covering layer 12 is removed. That is, the substrate intermediate 10A includes the plurality of bases 11 and the support member S1 that integrally supports the bases 11. The substrate intermediate 10A can be prepared by, for example, purchasing the support member S1 with the bases 11 already supported thereon. Alternatively, only the support member S1 may be prepared, and the bases 11 may be disposed on the support member S1. For example, the lead frame 13 obtained by processing a metal plate into a desired shape is prepared as the support member S1 and the lead frame 13 is set in a mold. Then, injection molding or the like is performed to prepare the substrate intermediate 10A in which the molded body 22 mainly composed of a resin as the base 11 is supported on the lead frame 13.

### (1-2) Step of Preparing the Plate-Shaped Member Having the Opening

Subsequently, a plate-shaped member having the opening is prepared. The plate-shaped member has a flat plate shape and includes an upper surface, a lower surface, and an opening penetrating from the upper surface to the lower surface. The upper and lower surfaces of the plate-shaped member are preferably parallel to each other. The upper surface and the lower surface of the plate-shaped member may be smooth or rough.

Similarly, an inner lateral surface of the opening of the plate-shaped member may also be smooth or rough. The upper, lower, and inner lateral surfaces may be in the same surface state or in different surface states. When the upper, lower, and inner surfaces of the plate-shaped member are rough surfaces, poor chemical wettability can be improved by the capillary action. That is, the resin member 12A can easily wet and spread. In addition, by forming the upper surface, the lower surface, and the inner surface of the plate-shaped member as smooth surfaces, it is possible to make the capillary action less likely to occur. For example, even when the plate-shaped member is made of a material having low wettability (material that repels the resin member), the rough surface allows the resin member to easily wet and spread due to the capillary action. On the other hand, when the plate-shaped member is made of a material having low wettability, the original wettability of the plate-shaped member can be maintained by making the upper, lower, and inner surfaces of the plate-shaped member be smooth.

For example, the wettability of the inner lateral surface of the opening of the plate-shaped member 30 can be made higher than the wettability of the upper surface of the plate-shaped member 30. Accordingly, the resin member 12A supplied from above a gap G between the outer lateral surface 11A of the base 11 and the inner lateral surface of the opening of the plate-shaped member can easily spread in the gap G. In addition, the wettability of the inner lateral surface of the opening of the plate-shaped member 30 can be made lower than that of the lower surface of the plate-shaped member 30. This reduces an excessive resin member 12A flowing downward on the outer lateral surface 11A of the base 11. The shape of the plate-shaped member and the like will be described in detail later.

The material of the plate-shaped member may be, for example, a metal, a ceramic, or a resin. A plating layer or a coating layer may be provided on each of the upper, lower, and inner lateral surfaces of the plate-shaped member. The plating layer may contain, for example, Au, Ag, Cu, Pt, Ni, or an alloy containing one of these metals, and may be provided in a single layer structure or a multiple layer structure. The material of the coating layer may be, for example, fluorine, silicone, or glass.

### (1-3) Step of Disposing the Plate-Shaped Member on the Support Member so as to Dispose the Base in the Opening of the Plate-Shaped Member

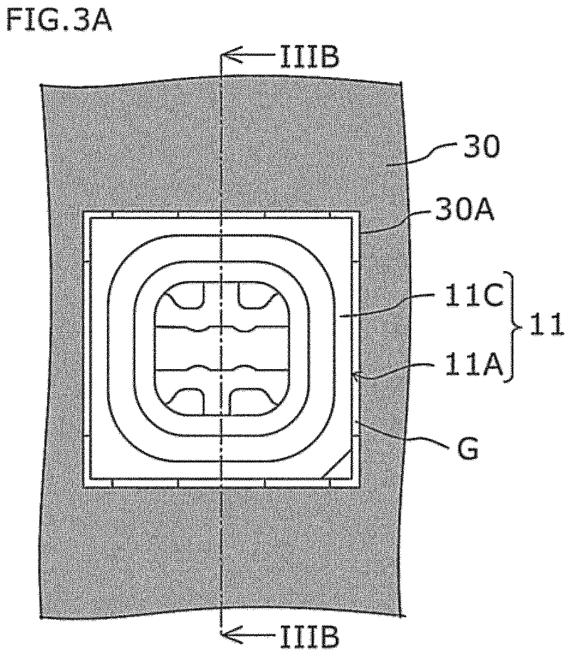

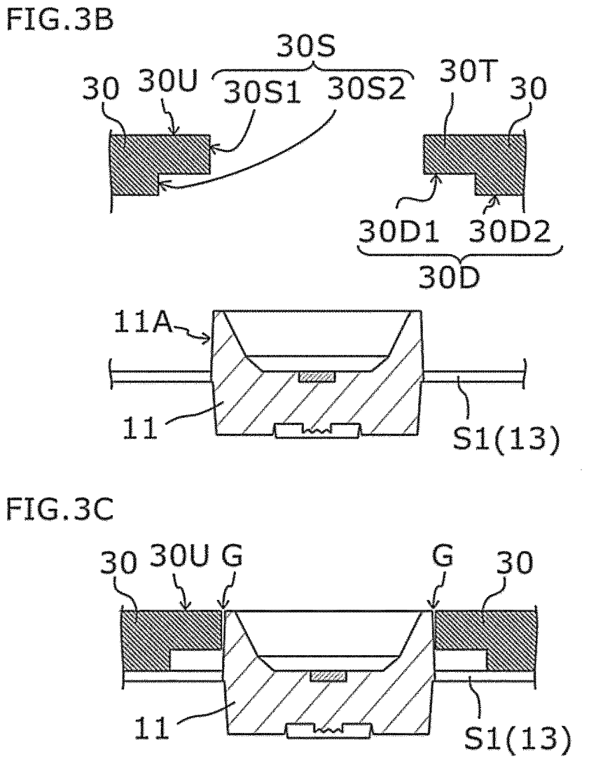

Subsequently, as illustrated in FIGS. 3A to 3C, the plate-shaped member 30 is disposed on the support member S1. FIG. 3B illustrates a state in which the plate-shaped member 30 is disposed at a position above and away from the support member S1. The plate-shaped member 30 is lowered to be disposed on the support member S1, as illustrated in FIG. 3C. In the drawing, only the end view of the plate-shaped member 30 cut of line IIIB-IIIB is illustrated.

The plate-shaped member 30 is disposed on the support member S1, while the base 11 is disposed in the opening 30A of the plate-shaped member 30. Specifically, the plate-shaped member 30 is disposed such that at least a portion of the inner lateral surface 30S defining the opening 30A of the plate-shaped member 30 and at least a portion of the outer lateral surface 11A of the base 11 face each other across the gap G. The plate-shaped member 30 may be disposed in contact with the support member S1. An upper surface 30U of the plate-shaped member 30 is preferably at the same height as the upper surface 11C of the base 11. This facilitates the resin member 12A to be disposed at the upper end of the outer lateral surface 11A of the base 11. When the resin member 12A is also disposed on the upper surface 11C of the base 11, the upper surface 30U of the plate-shaped member 30 may be disposed at a position higher than the upper surface 11C of the base 11. When the resin member 12A is disposed at a position apart from the upper end of the outer lateral surface 11A of the base 11, the upper surface 30U of the plate-shaped member 30 may be disposed at a position lower than the upper surface 11C of the base 11.

Preferably, the shape of the opening 30A of the plate-shaped member 30 and the outer peripheral shape of the upper surface 11C of the base 11 are similar shapes. For example, as illustrated in FIG. 3A, when the outer peripheral shape of the upper surface 11C of the base 11 is quadrangular, the shape of the opening 30A of the plate-shaped member 30 is also preferably quadrangular.

When the shape of the opening 30A of the plate-shaped member 30 and the outer peripheral shape of the upper surface 11C of the base 11 are similar shapes, the opening 30A preferably has such a size that the width of the gap G is uniform over the entire circumference of the opening 30A. That is, the center of the opening 30A of the plate-shaped member 30 and the center of the base 11 preferably coincide with each other in a top view. This can easily make the thickness of the covering layer 12 be the same on the four outer lateral surfaces 11A of the base 11.

A distance between the inner lateral surface 30S of the plate-shaped member 30 and the outer lateral surfaces 11A of the base 11, that is, a length of the gap G, can be set to, for example, a length in a range from 0.5 μm to 100 μm. For example, when the distance between one outer lateral surface 11A of the base 11 and the corresponding inner lateral surface 30S of the plate-shaped member 30 disposed facing the outer lateral surface 11A is not uniform, the length of the gap G is the length of the gap G at a portion having the smallest distance therebetween. For example, in the example illustrated in FIG. 3C, the outer lateral surface 11A of the base 11 is inclined relative to the upper surface 11C, and is not parallel to the inner lateral surface 30S of the plate-shaped member 30. In such a case, the gap G indicates the gap between the closest portions of these opposite surfaces. As illustrated in FIGS. 3B and 3C, when the inner lateral surface 30S of the plate-shaped member 30 includes a first inner lateral surface 30S1 and a second inner lateral surface 30S2 located on an outer side relative to the first inner lateral surface 30S1, the distance is the smallest between the lower end of the first inner lateral surface 30S1 and the outer lateral surface 11A of the base 11 opposite to the lower end, and the length of the gap G indicates the length of the gap G at this portion. A portion located on an inner side relative to the second inner lateral surface 30S2 is referred to as a protruding portion 30T. When such a protruding portion 30T is provided, a lower surface 30D includes a first lower surface 30D1 and a second lower surface 30D2 located below the first lower surface 30D1. In the example illustrated in FIG. 3B and the like, the upper surface of the protruding portion 30T coincides with the upper surface 30U of the plate-shaped member 30. That is, the protruding portion 30T is located on the upper side of the plate-shaped member 30. However, the shape may be inverted upside down, that is, the lower surface of the protruding portion 30T may coincide with the lower surface of the plate-shaped member. Alternatively, the protruding portion 30T may be shaped such that the upper surface is located below the upper surface 30U of the plate-shaped member 30 and the lower surface is located above the lower surface 30D of the plate-shaped member 30.

The inner lateral surface 30S of the opening 30A of the plate-shaped member 30 may be a surface perpendicular to or inclined with respect to the upper surface 30U or the lower surface 30D of the plate-shaped member 30.

The inner lateral surface 30S of the opening 30A of the plate-shaped member 30 can be provided with the protruding portion 30T protruding inward in the opening 30A, as illustrated in FIG. 3B. That is, the inner lateral surface 30S of the opening 30A includes the first inner lateral surface 30S1 located on the upper surface 30U side and the second inner lateral surface 30S2 located on the lower surface 30D side and on the outer side relative to the first inner lateral surface 30S1. In other words, the first inner lateral surface 30S1 is located on an inner side relative to the second inner lateral surface 30S2, and is the inner lateral surface of the protruding portion 30T. The first lower surface 30D1 is provided between the first inner lateral surface 30S1 and the second inner lateral surface 30S2. The upper surface of the protruding portion 30T coincides with the upper surface 30U of the plate-shaped member 30, and the first lower surface 30D1, which is the lower surface of the protruding portion 30T, is located apart from the second lower surface 30D2, which is the lower surface of the plate-shaped member 30. Accordingly, the first lower surface 30D1 of the protruding portion 30T of the plate-shaped member 30 can be disposed apart from the upper surface of the support member S1.

When the plate-shaped member 30 includes the protruding portion 30T in a part of the inner lateral surface 30S of the opening 30A as described above, the distance of the space between the first inner lateral surface 30S1, which is the inner lateral surface of the protruding portion 30T, and the outer lateral surface 11A of the base 11 corresponds to the gap G described above. The resin member 12A is in contact with both the first inner lateral surface 30S1 and the outer lateral surface 11A of the base 11, and is held by these two opposite surfaces. That is, the resin member 12A is not disposed on the second inner lateral surface 30S2, causing the support member S1 to be less likely to come into contact with the resin member 12A. In this way, the wetting and spreading range of the resin member 12A can be adjusted according to the length of the first inner lateral surface 30S1. The distance between the second inner lateral surface 30S2 and the first inner lateral surface 30S1, that is, the length of the first lower surface 30D1 is preferably set to such a distance that the resin member 12A is not disposed on the second inner lateral surface 30S2 when the resin member 12A wets and spreads.

When the plate-shaped member 30 includes the first inner lateral surface 30S1 and the second inner lateral surface 30S2, the thickness of the plate-shaped member 30, that is, the distance between the upper surface 30U and the lower surface 30D, is preferably substantially equal to the height of the base 11 located above the upper surface of the support member S1 of the substrate 10. However, when an adjustment member (such as a spacer) for adjusting the distance between the plate-shaped member 30 and the support member S1 is disposed therebetween, the plate-shaped member 30 needs to have a thickness corresponding to the vertical width (height) of the resin member (covering layer) to be disposed on the outer lateral surface 11A of the base 11. When the inner lateral surface 30S of the opening 30A of the plate-shaped member 30 does not include the first inner lateral surface 30S1 and the second inner lateral surface 30S2, the thickness of the plate-shaped member 30, that is, the distance between the upper surface 30U and the lower surface 30D is preferably smaller than the height of the base 11 located above the upper surface of the support member S1 of the substrate 10, and a spacer or the like is preferably used. The plate-shaped member 30 may have a leg portion serving as a spacer.

When the inner lateral surface 30S of the opening 30A of the plate-shaped member 30 includes the first inner lateral surface 30S1 and the second inner lateral surface 30S2 as illustrated in FIG. 3B, the length of the first inner lateral surface 30S1 may be, for example, 0.1 mm or more. Since the upper limit of the length of the first inner lateral surface 30S1 varies depending on the thickness of the plate-shaped member 30 (the distance between the upper surface and the lower surface), the length of the second inner lateral surface 30S2 can be adjusted to 0.1 mm or more. A region in which the resin member 12A is disposed in a step described later is determined according to the length of the first inner lateral surface 30S1.

(1-4) Step of Supplying the Resin Member to the Gap Such that it Covers the Outer Lateral Surface of the Base

Subsequently, the resin member 12A is supplied to the gap G between the outer lateral surface 11A of the base 11 and the inner lateral surface 30S of the opening 30A of the plate-shaped member 30 to cover the outer lateral surface of the base. The resin member 12A is in a liquid state or a sol-like state at this point of time. The resin member 12A may be supplied, for example, from the opening of a mask using a jet dispenser, a potting dispenser, or the like. The resin member 12A is supplied from above the upper surface 30U of the plate-shaped member 30. A viscosity of the resin member 12A is, for example, preferably about 10 Pa·s/0.5 rpm or 1 Pa·s/50 rpm or less at 25° C.

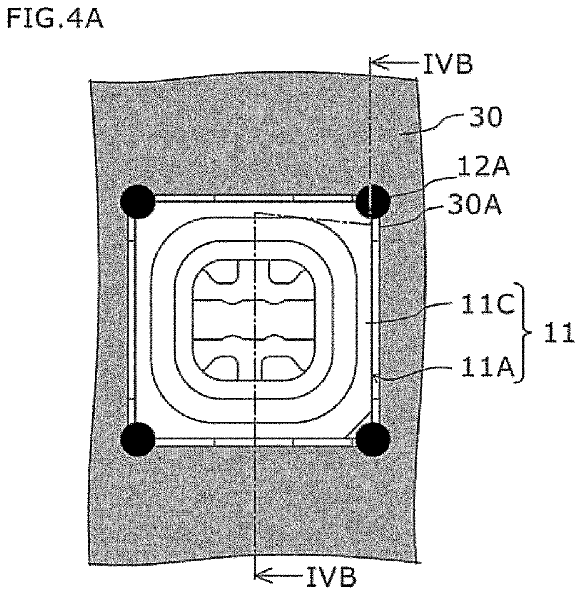

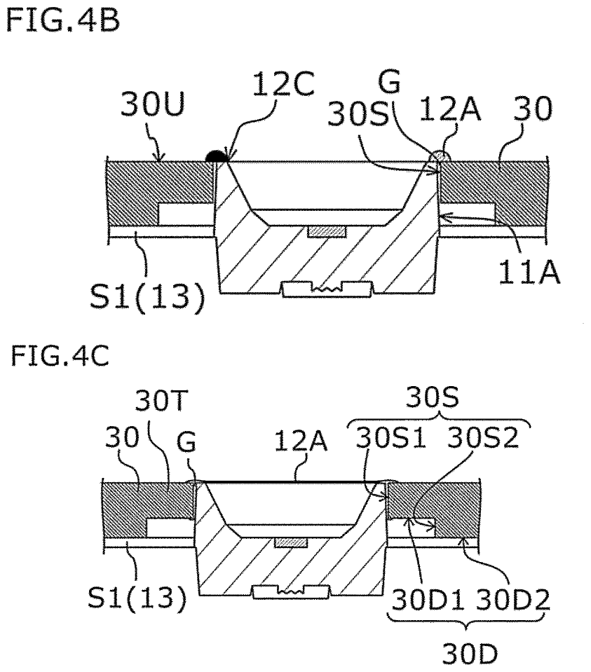

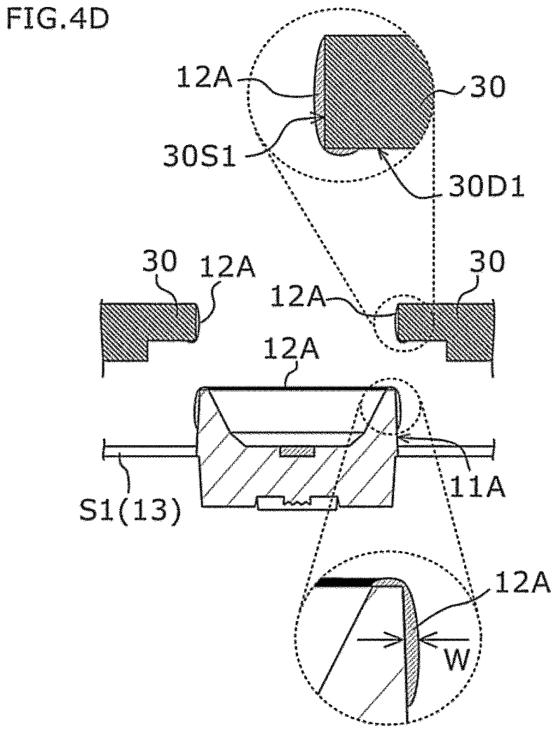

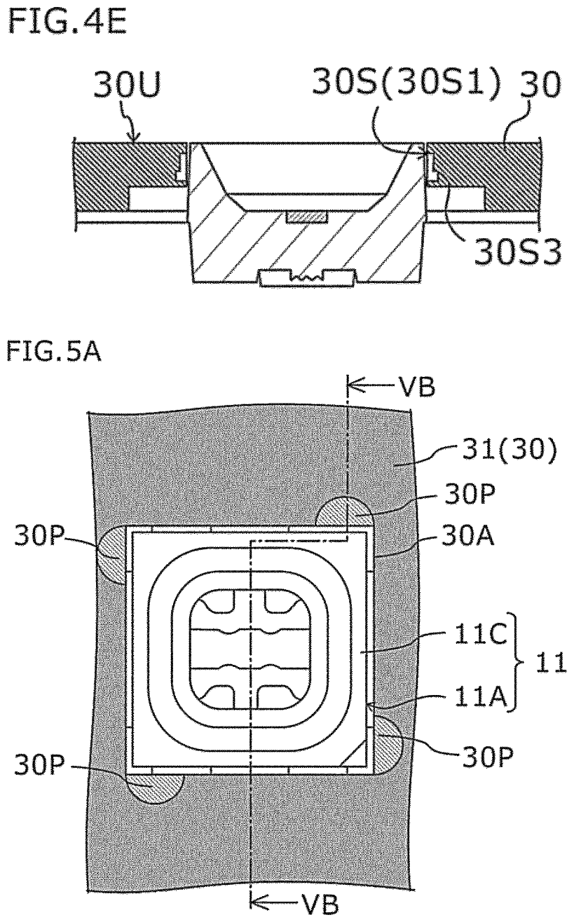

The resin member 12A can be supplied only to the gap G. Alternatively, as illustrated in FIGS. 4A and 4B, the resin member 12A can be supplied extending across the upper surface 11C of the base 11 and the upper surface 30U of the plate-shaped member 30. Accordingly, the supplied resin member 12A flows so as to come into contact with both the inner lateral surface 30S of the opening 30A of the plate-shaped member 30 and the outer lateral surface 11A of the base 11, and the resin member 12A is disposed in the gap G. In a plan view, the resin member 12A can be disposed entirely or partially in the gap G located outside the outer lateral surfaces 11A of the base 11. For example, as illustrated in FIG. 4A, when the shape of the outer periphery of the upper surface 11C of the base 11 is quadrangular in a plan view, the resin members 12A can be separately supplied to the outer lateral surfaces 11A and their vicinities at four corners of the quadrangle. Thus, even when the resin members 12A are supplied to a plurality of locations of one continuous gap G, the width of the gap G can be adjusted to the above-mentioned width to allow the resin member 12A to flow in the lateral direction (toward the adjacent corner) due to the interfacial tension. As a result, as illustrated in FIG. 4C, the resin members 12A can be disposed not only on the outer lateral surfaces 11A located at the portion where the resin member 12A is supplied, but also on the outer lateral surface 11A interposed therebetween. When the resin member 12A flows laterally in the gap G, the resin member 12A may also flow on the upper surface 30U of the plate-shaped member 30 or the upper surface 11C of the base 11. Thus, the resin members 12A supplied to separate positions flow laterally to form the resin member 12A continuously, as illustrated in FIG. 4C. However, the flowing resin members 12A need not be formed continuously and may be separate.

The supply amount of the resin member 12A can be adjusted in accordance with the size of the outer lateral surface 11A of the base 11, and further, in accordance with the size (area) of the outer lateral surface 11A on which the covering layer 12 is to be disposed. When the resin members 12A are supplied to a plurality of locations using a dispenser such as an air dispenser or a jet dispenser, for example, the resin members 12A can be simultaneously supplied thereto using a plurality of nozzles connected to a single syringe. This can also be done simultaneously or at different timings using a plurality of syringes each having one nozzle connected thereto. A jet dispenser with one nozzle connected to one syringe may be used to supply the resin members 12A to a plurality of different locations by moving the nozzle. The resin member 12A may be supplied several times at the same position. In this case, the resin member 12A may be cured to form the covering layer 12 in the succeeding step, followed by disposing of the resin member 12A again on the covering layer 12. Alternatively, the resin member 12A may be newly disposed so as not to partially or entirely overlap the covering layer 12.

As illustrated in FIG. 4C, when the inner lateral surface 30S of the opening 30A of the plate-shaped member 30 includes the first inner lateral surface 30S1, which is the inner lateral surface of the protruding portion 30T, the length of the first inner lateral surface 30S1 is shorter than the length of the outer lateral surface 11A of the base 11. In such a case, the resin member 12A protruding downward beyond the first inner lateral surface 30S1 includes a portion spreading downward on the outer lateral surface 11A of the base 11 and a portion spreading to the first lower surface 30D1, which is the lower surface of the protruding portion 30T. This occurs because of the surface tension (interfacial tension) acting on the resin member 12A having fluidity, and this can reduce the likelihood of the resin member 12A flowing downward and coming into contact with the support member S1. That is, at the first lower surface 30D1 provided continuously with the first inner lateral surface 30S1, a space where the excessive resin member 12A can escape is formed by providing the first lower surface 30D1 at a position apart from the support member S1, thus facilitating the resin member 12A to be disposed at a desired region. Thus, controlling the placement area of the resin member 12A using the space between the plate-shaped member 30 and the outer lateral surface 11A of the base 11 is difficult when a molding method such as injection molding or compression molding is employed. Similarly, in a method like screen printing that does not use the plate-shaped member facing the outer lateral surface 11A of the base 11, the resin member 12A can be disposed on the outer lateral surface 11A of the base 11, but it is difficult to control the region where the resin member 12A spreads, especially the position of the lower end of the resin member 12A disposed on the outer lateral surface 11A of the base 11.

In the plate-shaped member 30 illustrated in FIG. 4B, the opening 30A including the first inner lateral surface 30S1 and the second inner lateral surface 30S2 is illustrated. Alternatively, when the thickness of the entire plate-shaped member 30 is equivalent to the thickness of the first inner lateral surface 30S1, that is, when the entire plate-shaped member 30 is thin, the position of the lower end of the resin member 12A can be controlled as described above even without the second inner lateral surface 30S2. In this case, the upper surface 30U of the plate-shaped member 30 and the upper surface 11C of the base 11 are preferably disposed so as to be substantially horizontal to each other.

As illustrated in FIG. 4E, the inner lateral surface 30S (first inner lateral surface 30S1) of the plate-shaped member 30 may have a lateral surface groove 30S3. The lateral surface groove 30S3 is disposed separated from the upper surface 30U and the lower surface 30D (first lower surface 30D1). The resin member 12A can also be made to flow into the lateral surface groove 30S3.

### (1-5) Step of Curing the Resin Member to Form the Covering Layer Covering the Lateral Surface of the Base

Subsequently, the resin member 12A is cured. Specifically, the resin member 12A is cured by heating. Accordingly, the covering layer 12 is formed. A heating temperature can be, for example, in a range from 60° C. to 200° C. A heating time can be, for example, in a range from 5 minutes to 480 minutes.

Before curing of the resin member 12A, the plate-shaped member 30 is moved to a position away from the support member S1, as illustrated in FIG. 4D. After the plate-shaped member 30 is removed, the surface tension (interfacial tension) acts on the resin member 12A disposed on the outer lateral surface 11A of the base 11. As a result, the thickness W of the resin member 12A in the lateral direction is thicker near the center than at the upper and lower ends on the outer lateral surface 11A of the base 11. Fine particles of carbon black or the like in the resin member 12A, if contained, lower the concentration at the end portions. As illustrated in FIG. 4D, a part of the resin member 12A is in a state of adhering to the inner lateral surface 30S (30S1) of the opening of the plate-shaped member 30. In some cases, the resin member 12A also adheres to the lower surface 30D (30D1) of the plate-shaped member 30. However, when the surface of the plate-shaped member 30 has a low wettability with respect to the resin member, the resin member 12A does not adhere to the plate-shaped member 30 in some cases. The resin member 12A may be cured without moving the plate-shaped member 30. For example, when the adhesive force between the resin member 12A and the outer lateral surface 11A of the base 11 is higher than the adhesive force between the resin member 12A and the plate-shaped member 30, the covering layer 12 can be disposed on the outer lateral surface 11A of the base 11 while the cured covering layer 12 is peeled off from the plate-shaped member 30.

The substrate 10 as illustrated in FIG. 1A and the like can be obtained through the steps describe above.

In the following, a case of using a variation of the plate-shaped member that can be used in the steps described above is described.

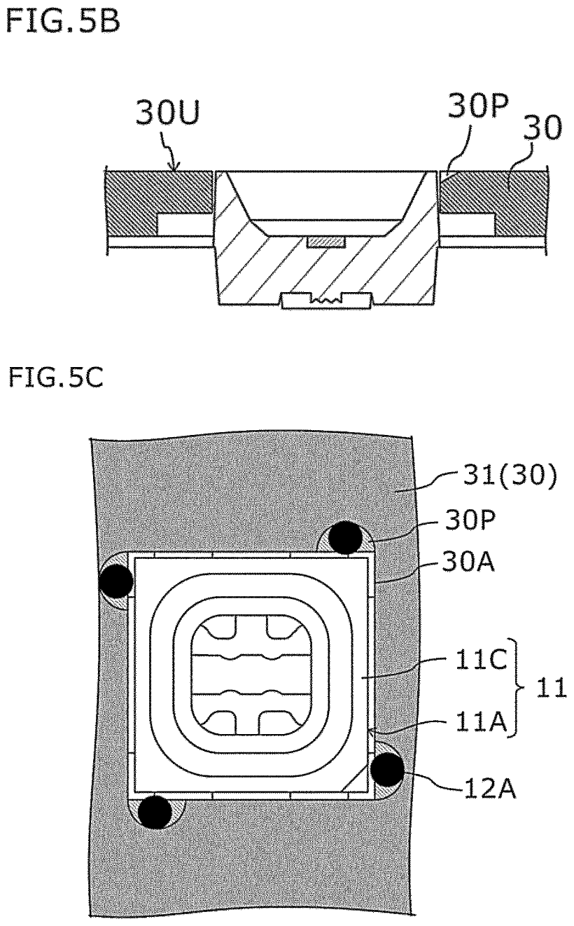

A plate-shaped member 31 according to a variation is illustrated in FIGS. 5A and 5B. FIG. 5B is a cross-sectional view of line VB-VB of FIG. 5A. The shape of the opening 30A in a top view of the plate-shaped member 31 is partially different from the outer peripheral shape of the upper surface 11C of the base 11. Specifically, in the case of the base 11 in which the outer peripheral shape of the upper surface 11C is quadrangular, the upper surface 30U of the plate-shaped member 31 has a dent 30P continuous with the opening 30A. The dent 30P is continuous from a part of the inner lateral surface 30S facing each of the four outer lateral surfaces 11A of the base 11, and is disposed at a position facing each of the four corners of the base 11. The shape of the dent 30P in a top view may be quadrangular, triangular, or the like instead of the semicircular shape as illustrated in FIG. 5A. As illustrated in FIG. 5B, the dent 30P can have an inclined surface inclining downward from the upper surface 30U in a cross-sectional view.

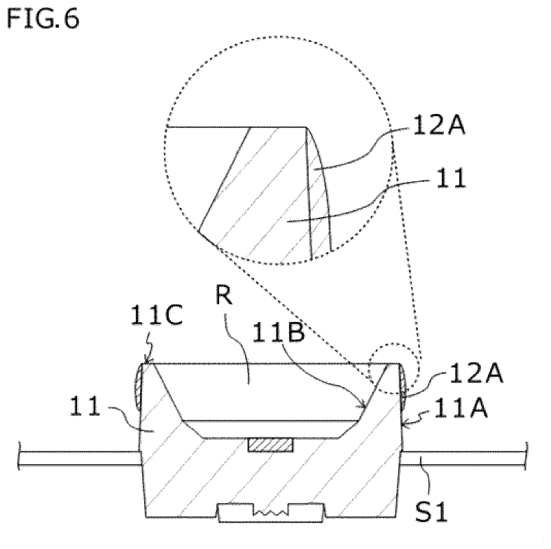

Thus, with the dent 30P continuous with the inner lateral surface 30S of the opening 30A and recessed in the upper surface 30U, the resin member 12A can be supplied to the dent 30P as illustrated in FIG. 5C. This allows the resin member 12A to be disposed in the gap G continuous with the dent 30P. That is, the resin member 12A can be supplied to the gap G without supplying the resin member 12A onto the upper surface 11C of the base 11. As illustrated in FIG. 6, the resin member 12A is less likely to be disposed on the upper surface 30U of the base 11.

Regarding the dent 30P, in the example illustrated in FIG. 5A, the four dents 30P are provided corresponding to the four respective outer lateral surfaces 11A of the base 11, and the dents 30P are provided at corresponding positions close to the respective corners of the upper surface 11C of the base 11. The position or shape of the dent 30P is not limited to this example. For example, the dent 30P may be provided at a position away from the corner of the outer lateral surface 11A of the base 11. Two or more dents 30P may be provided with respect to one outer lateral surface 11A. The dent 30P need not be provided at a part of the outer lateral surface 11A of the base 11. The top view shape of the dent 30P can be a semicircular shape, a polygonal shape such as a quadrangle or a triangle, a semi-elliptical shape, or a combination of these shapes. For example, when the resin member 12A is supplied in a size of about 0.5 mm and wets and spreads to a size of about 1 mm, a width of the dent 30P (a distance from the boundary between the recessed portion and the portion other than the recessed portion to the most distant position) in a top view can be set to a width in a range from 0.5 mm to 1 mm. This case enables the following: the resin member 12A is supplied into the dent 30P, while the resin member 12A is not supplied to the upper surface 11C of the base 11.

The cross-sectional shape of the dent 30P may be a surface parallel to the upper surface 30U, or a concave curved surface or a convex curved surface, other than the inclined surface as illustrated in FIG. 5B. When the upper surface 30U of the plate-shaped member 30 is at the same height as the upper surface 11C of the base 11, a depth of the dent 30P (a distance from the upper surface 30U to the most distant position) may be, for example, 0.1 mm from the upper surface 30U of the plate-shaped member 30.

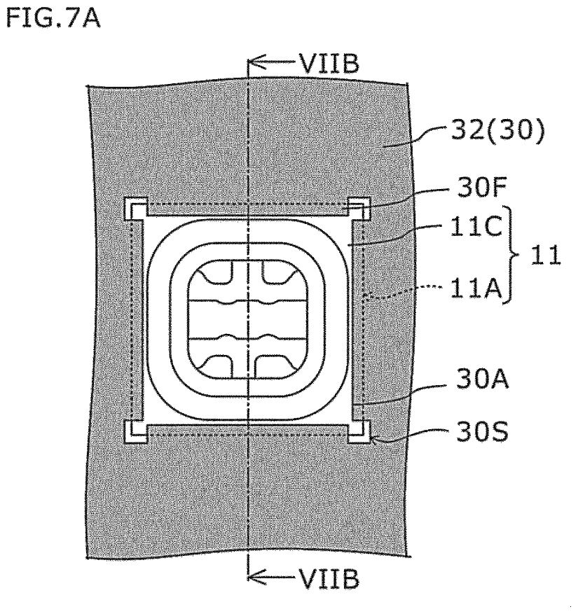

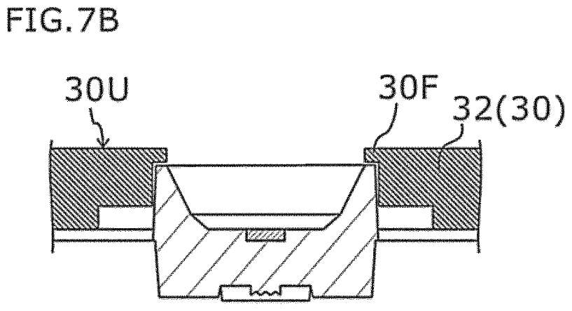

FIGS. 7A and 7B illustrate a plate-shaped member 32 according to another variation. FIG. 7B is a cross-sectional view of line VIIB-VIIB of FIG. 7A. In the plate-shaped member 32, the shape of the opening 30A in a top view is partially different from the outer peripheral shape of the upper surface 11C of the base 11. Specifically, with respect to the base 11 in which the outer peripheral shape of the upper surface 11C is quadrangular, the inner lateral surface 30S of the opening 30A of the plate-shaped member 32 is provided with a canopy portion 30F overlapping the upper surface 11C of the base 11. The canopy portion 30F is disposed at each of portions including four sides of the upper surface 11C of the base 11, via a gap. At the portions corresponding to the four corners of the base 11, the upper surface 11C of the base 11 is not covered with the canopy portion 30F, and the inner lateral surface 30S of the opening 30A is located on an outer side of the outer lateral surface 11A. The canopy portion 30F is disposed so as not to overlap the recessed portion R of the base 11. The distance (gap) between the lower surface of the canopy portion 30F and the upper surface 11C of the base 11 is, for example, in a range from 0 mm to 0.025 mm.

When such a plate-shaped member 32 is used, the resin member 12A is disposed extending across the portion of the upper surface 11C of the base 11 not covered with the canopy portion 30F and the upper surface of the plate-shaped member 32 disposed on an outer side of the upper surface 11C. As a result, the resin member 12A disposed in the gap G between the inner lateral surface 30S of the opening 30A of the plate-shaped member 32 and the outer lateral surface 11A of the base 11 spreads laterally due to the interfacial tension, and the resin member 12A can also spread due to the interfacial tension in the gap between the lower surface of the canopy portion 30F of the plate-shaped member 32 and the upper surface 11C of the base 11. When the distance between the lower surface of the canopy portion 30F and the upper surface 11C of the base 11 is 0 mm, that is, these surfaces are in contact with each other, a new gap is formed between the lower surface of the canopy portion 30F and the upper surface 11C of the base 11 when the plate-shaped member 32 is moved upward before the resin member 12A is cured. Subsequently, the resin member 12A flows into the newly formed gap. Thus, the resin member 12A can be disposed on the upper surface 11C of the base 11. When the resin member 12A is cured in a state in which the lower surface of the canopy portion 30F and the upper surface 11C of the base 11 are in contact with each other, the resin member 12A is less likely to be disposed on the upper surface 11C of the base 11 covered with the canopy portion 30F.

### Substrate Manufacturing Method 2

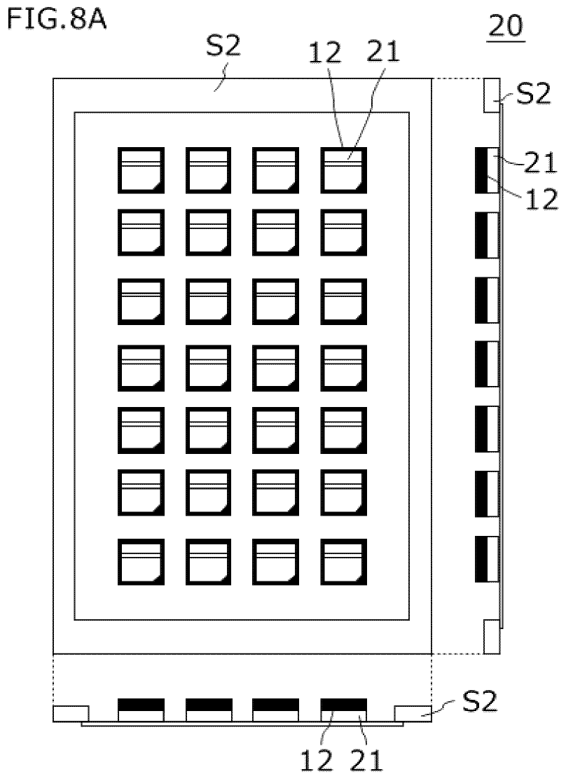

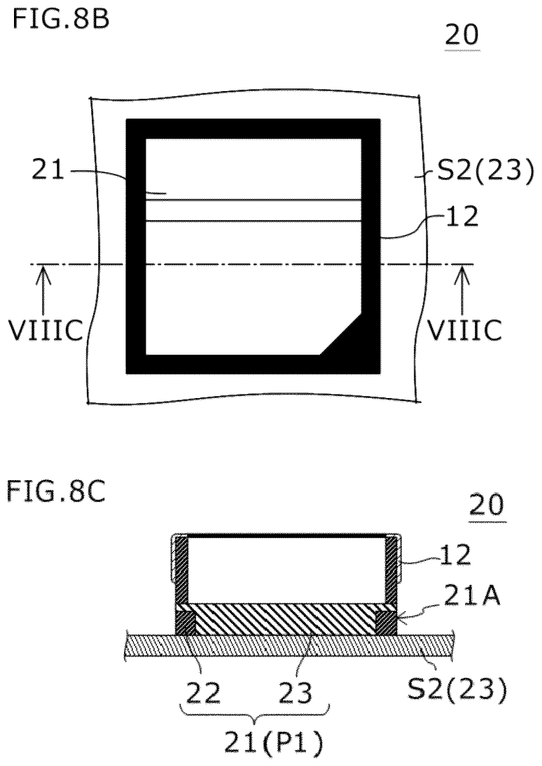

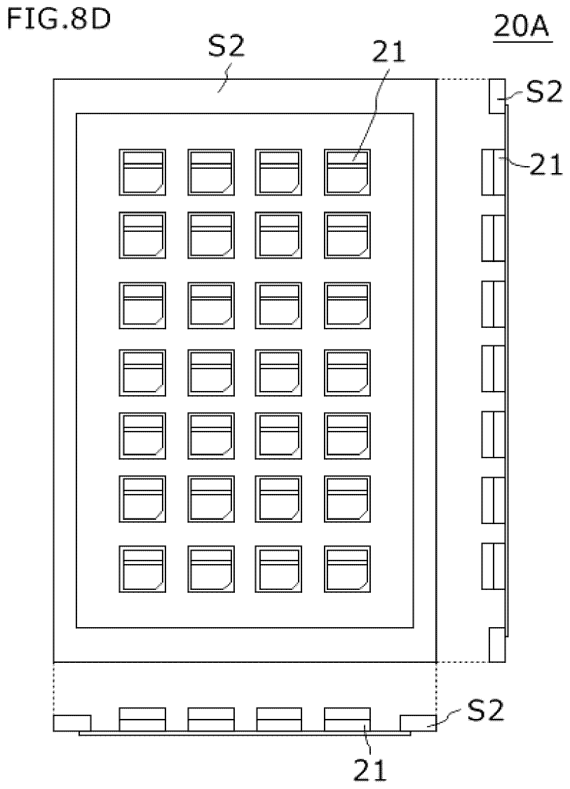

FIG. 8A illustrates a top view illustrating a substrate 20 obtained by a substrate manufacturing method according to the present embodiment and two side views seen vertically and laterally. FIG. 8B is an enlarged top view of a portion including one base 21 of the substrate 20 illustrated in FIG. 1A. FIG. 8C is a cross-sectional view of line VIIIC-VIIIC of FIG. 8B. FIG. 8D illustrates a substrate intermediate 20A used in the substrate manufacturing method according to the present embodiment.

As in the substrate manufacturing method 1, the substrate 20 obtained in the substrate manufacturing method 2 includes the base 21, the covering layer 12 disposed on an outer lateral surface 21A of the base 21, and a support member S2. The substrate 20 according to the present embodiment uses a sheet member 23 having adhesiveness as the support member S2, and the base 21 is disposed on the upper surface of the support member S2. A package P1 of a light-emitting device including the base 21 and the covering layer 12 can be obtained by removing the base 21 from the support member S2. That is, the support member S1 partially forms a portion of the light-emitting device in the substrate manufacturing method 1, while the support member S2 is not included in the light-emitting device in the substrate manufacturing method 2.

In the present embodiment, the sheet member 23 serving as the support member S2 may have a conductive property, an insulating property, or a combination thereof. The sheet member 23 is, for example, quadrangular or circular in a top view. The size of the sheet member 23 that has a quadrangular shape, for example, is in a range from 41 mm to 100 mm in length on a short side, in a range from 100 mm to 200 mm in length on a long side, and in a range from 0.035 mm to 0.2 mm in thickness. In a case in which the support member S2 has a circular shape, the diameter thereof is in a range from 100 mm to 300 mm and the thickness thereof is in a range from 0.035 mm to 0.2 mm. For example, the material of the sheet member 23 can be similar to the material mentioned in the substrate manufacturing method 1, if the material is conductive. In the case in which the material of the sheet member 23 is an insulating material, for example, a resin material such as a phenol resin, an epoxy resin, a polyimide resin, polyethylene terephthalate, polycarbonate, polyethylene naphthalate, a silicone resin, polyphthalamide, or a liquid crystal polymer can be used. The sheet member 23 may be adhesive itself or may be made of a non-adhesive member having a surface provided with an adhesive agent. For example, as illustrated in FIG. 8A, the support member S2 including a metal frame and a UV sheet held in the frame can be used. The UV sheet is a resin sheet having a surface provided with the adhesive agent, and the adhesiveness thereof lowers when the UV sheet is irradiated with UV light.

In the present embodiment, the base 21 is a member for holding a light-emitting element in the light-emitting device described later. As the material of the base 21, a ceramic material such as aluminum oxide or aluminum nitride, a metal material such as aluminum or copper, or the like can be used other than the resin material described in the substrate manufacturing method 1. In the present embodiment, the base 21 is the package P1 provided with the resin molded body 22 and the conductive member 23, and is supported, by the support member S2, in the state of the package P1 provided with the covering layer 12 on the outer lateral surface of the molded body 22, that is, the outer lateral surface 21A of the base 21. Examples of the base 21 include a resin package in which a lead is buried in a base made of a resin material, a ceramic package including wiring line, and the like. Such a base 21 is supported by the support member S2 such that the lower surface of the base 21 and the upper surface of the support member S2 face each other.

For the covering layer 12, a material similar to the material described as an example in the substrate manufacturing method 1 can be used.

For the method for manufacturing such a substrate 20, steps similar to those of the substrate manufacturing method 1 can be used. In the present embodiment, as illustrated in FIG. 8D, all the bases 21 (packages P1) are disposed on the upper surface of the support member S2 in the substrate intermediate 20A.

### Second Embodiment

A light-emitting device obtained by a method for manufacturing a light-emitting device according to the present embodiment includes a package and a light-emitting element held by the package. The package includes a base, a covering layer disposed on an outer lateral surface of the base, and a conductive member.

The following methods may be used to manufacture such a light-emitting device. One method is to prepare the substrate intermediate used in the first embodiment, dispose a light-emitting element on a substrate of the substrate intermediate to form a light-emitting device intermediate, and then dispose a covering layer on the base of the substrate (light-emitting device manufacturing method 1). Another method is to prepare the substrate according to the first embodiment, that is, the substrate provided with the covering layer, and mount a light-emitting element on a base of the substrate (light-emitting device manufacturing method 2).

FIGS. 9A and 9B illustrate a top view and a side view of a light-emitting device 100 obtained by the method for manufacturing the light-emitting device according to the present embodiment. FIG. 9C is a cross-sectional view of line IXC-IXC of FIG. 9A. A light-emitting device 100 includes the package P1 and a light-emitting element 14. The package P1 includes the base 11 and the covering layer 12 disposed on the outer lateral surface 11A of the base 11. The base 11 includes the molded body 22 and the conductive member 13. The light-emitting device 100 can further include, for example, a wire 15 that bonds the light-emitting element 14 and the conductive member 13 and a light-transmissive member 17 that seals the light-emitting element 14 and the like.

A known semiconductor light-emitting element can be employed as the light-emitting element 14. In the present embodiment, a light-emitting diode is exemplified as the light-emitting element. Regarding the light-emitting element, a light-emitting element using a nitride-based semiconductor (InₓAl_{y}Ga_{1-x-y}N, 0≤X, 0≤Y, X+Y≤1) can be used, for example, as a light-emitting element that emits blue light (having a peak wavelength in a range from 430 nm to 490 nm) or green light (having a peak wavelength in a range from 495 nm to 565 nm). As a light-emitting element that emits red light (having a peak wavelength in a range from 610 nm to 700 nm), GaAlAs, AlInGaP, or the like can be used other than the nitride-based semiconductor element described above. The shape of the light-emitting element in a plan view can be a quadrangular shape, such as a square shape or a rectangular shape, or a polygonal shape, such as a triangular shape or a hexagonal shape. In the example illustrated in FIG. 9A and the like, the light-emitting device 100 includes three light-emitting elements 14 consisting of a blue light-emitting element, a green light-emitting element, and a red light-emitting element. For example, the light-emitting device 100 applicable to a display can include three light-emitting elements consisting of a blue light-emitting element, a green light-emitting element, and a red light-emitting element to allow full-color display.

The light-emitting device 100 also includes a bonding member that bonds the light-emitting element 14 and the conductive member 13. As the bonding member, an insulating bonding member or a conductive bonding member can be used. Examples of the insulating bonding member include resin materials such as silicone and epoxy. Examples of the conductive bonding member include bumps containing metals such as gold, silver, copper, conductive paste, or eutectic solder such as Au—Sn, and the like.

The wire 15 is a member that electrically connects the conductive member 13 and the light-emitting element 14. Examples of the material of the wire 15 include gold, silver, aluminum, alloys thereof, and the like.

The light-transmissive member 17 protects the light-emitting element 14 and the like, and is disposed in the recessed portion R. Examples of the resin material used for the light-transmissive member 17 include, for example, thermosetting resins such as an epoxy resin, a modified epoxy resin, a silicone resin, and a modified silicone resin. The light-transmissive member 17 may contain a diffusing material such as barium titanate, titanium oxide, aluminum oxide, or silicon oxide. The light-transmissive member 17 may also contain a pigment or a dye.

A light-emitting device 200 illustrated in FIG. 10 includes, as the base 11, the molded body 22 and the light-shielding layer 18. In the example illustrated in FIG. 10, the covering layer 12 covers the outer lateral surface 11A and the upper surface 11C of the base 11 including the light-shielding layer 18. However, the light-shielding layer 18 may be exposed from the covering layer 12.

As the light-shielding layer 18, for example, a resin material containing carbon black or titanium black as a light-absorbing substance may be used. The light-shielding layer 18 may be made of the same material as that of the covering layer 12, or may be made of a different material. The light-shielding layer 18 preferably covers the entire upper surface of the molded body 22. The upper surface of the light-shielding layer 18 may be a flat surface or a surface having irregularities. When the light-emitting device is used as a display, the upper surface of the light-shielding layer 18 is preferably a surface having irregularities. When the light-shielding layer 18 having irregularities on the upper surface thereof is exposed from the covering layer 12, the external light is scattered to reduce shine. When the light-shielding layer 18 having irregularities on the upper surface thereof is covered with the covering layer 12 such that the irregularities are covered, the adhesiveness between the light-shielding layer 18 and the covering layer 12 can be improved. In particular, when the light-emitting device is used in a severe use environment, for example, when the light-emitting device is used as an outdoor display, since the covering layer 12 is disposed with good adhesion, the likelihood of occurrence of problems such as peeling of the covering layer 12 can be reduced.

The thickness of the light-shielding layer 18 can be, for example, in a range from 1 μm to 25 μm. When the covering layer 12 is a light-shielding covering layer 12 containing carbon black or the like as a light-absorbing substance, the gap in the light-shielding layer 18 that has cracked due to thermal contraction of the base 11 or curing and contraction of the light-shielding layer 18 itself can be filled by covering the upper surface of the light-shielding layer 18 with the covering layer 12. The light-shielding layer 18 can be formed by printing, stamping, injection molding, compression molding, or the like.

### Light-Emitting Device Manufacturing Method 1

A light-emitting device manufacturing method 1 includes the following steps:
(2-1) Step of preparing the substrate intermediate including the base and the support member supporting the base
(2-2) Step of disposing the light-emitting element on the base
(2-3) Step of preparing the plate-shaped member having an opening
(2-4) Step of disposing the plate-shaped member on the support member so as to dispose the base in the opening of the plate-shaped member
(2-5) Step of disposing the resin member in the gap between the lateral surface of the base and the plate-shaped member
(2-6) Step of curing the resin member to form the covering layer covering the lateral surface of the base

The above steps are similar to those in the first embodiment except for the step (2-2). That is, the step (2-1) is similar to the step (1-1) of the first embodiment, the step (2-3) is similar to the step (1-2), the step (2-4) is similar to the step (1-3), the step (2-5) is similar to the step (1-4), and the step (2-6) is similar to the step (1-5), and the description of these steps is omitted.

The step (2-2) is described in detail below.

### (2-2) Step of Disposing the Light-Emitting Element on the Base

The light-emitting element 14 is disposed in the recessed portion R of each base 11 of the substrate intermediate 10A illustrated in FIG. 2A. For example, a bonding member such as a resin is disposed on the bottom surface R1 defining the recessed portion R, and the light-emitting element 14 is disposed thereon. The light-emitting element 14 can be disposed at a desired position on the bottom surface R1 defining the recessed portion R by, for example, adsorbing and holding the light-emitting element 14 using a collet.

This step can also include a step of disposing members such as the wire 15 and the light-transmissive member 17.

The wire 15 can be disposed using a wire bonder or the like. The light-transmissive member 17 can be formed by disposing a liquid resin material in the recessed portion R by potting, spraying, or the like, and then curing the resin material by heating at a temperature in a range from 60° C. to 200° C., for example.

In addition to the light-emitting element 14, a protective element such as a Zener diode can be disposed, if necessary. A light-reflecting member such as a white resin may be disposed around the light-emitting element 14 by potting, printing, or the like. When the conductive member 13 is made of a material containing silver, a protective films made of titanium oxide, aluminum oxide, or the like may be disposed by sputtering, vapor deposition, atomic deposition (ALD), or the like, for the purpose of, for example, reducing sulfurization of silver.

Finally, subsequent to the step (2-6) of forming the covering layer 12, the lead frame 13, which is the support member S1, is cut at a desired position, or a part of the lead frame 13 (suspended lead 13C) buried in the base 11 is removed from the base 11; thus, the individual light-emitting device 100 as illustrated in FIG. 9A can be obtained. In the present embodiment, the support member S1 is the lead frame 13, and a step of bending a portion to be the outer lead 13B of the light-emitting device 100 into a desired shape may be provided before removing the base 11 from the lead frame 13.

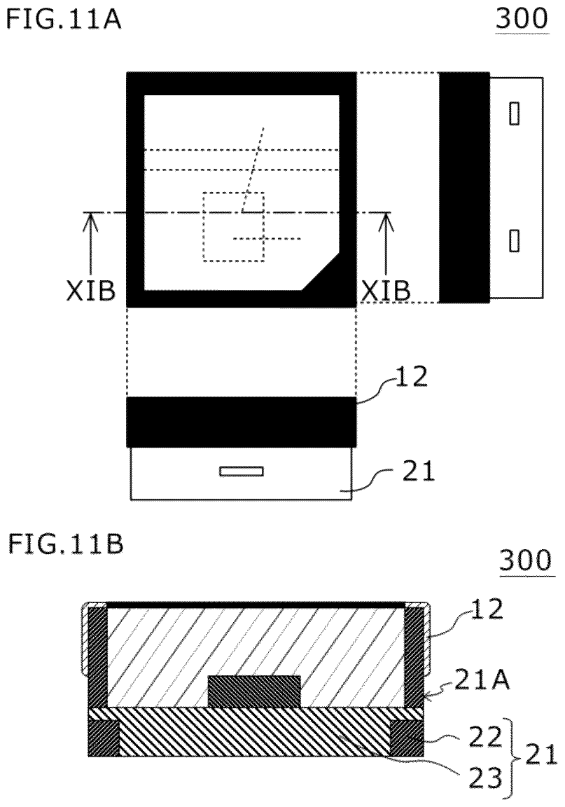

When the sheet member is used as the support member S2 as illustrated in FIG. 8D, a step of removing the light-emitting device 300 held by the support member (sheet member) S2 is provided. As a result, the light-emitting device 300 as illustrated in FIGS. 11A and 11B can be obtained.

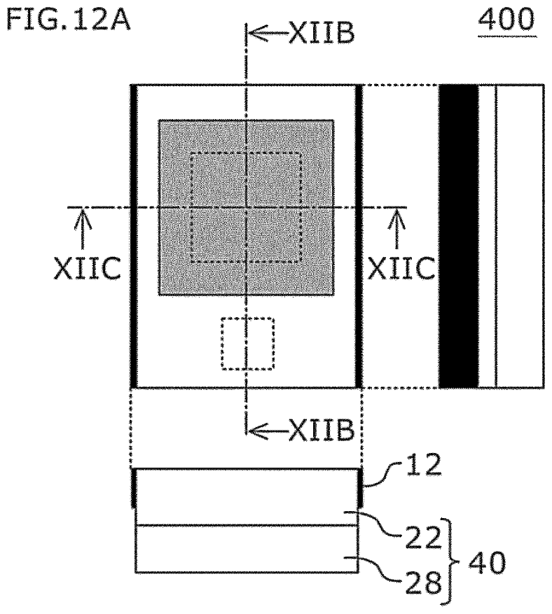

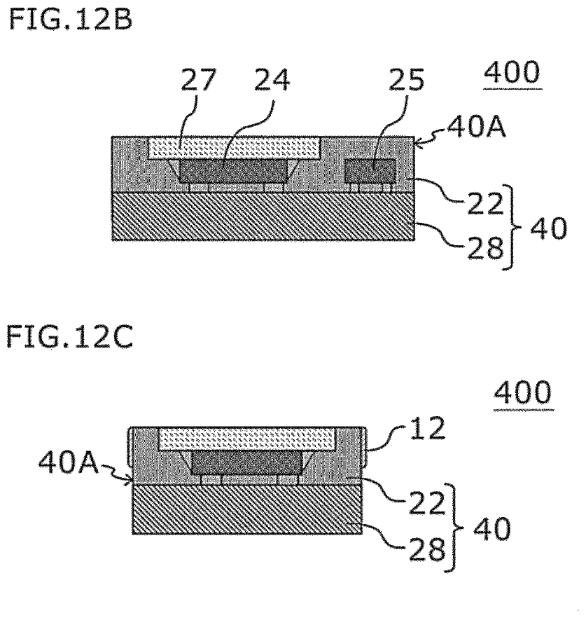

In addition, a light-emitting device 400 as illustrated in FIGS. 12A and 12B has a structure in which a base 40 does not have the recessed portion, and the base 40 includes the molded body 22 and a wiring board 28. The molded body 22 and the light-emitting element 24 are in contact with each other. In the case of the light-emitting device 400 with such a structure, since it is practically impossible to obtain the substrate intermediate, the light-emitting device 400 can be obtained by a method in which, first an intermediate member including a plurality of light-emitting device intermediates each including the base and the light-emitting element(s) without the covering layer is formed, and then the covering layer is formed in each of the light-emitting device intermediates using the plate-shaped member in the same manner described above. In the light-emitting device 400, the covering layer 12 is disposed on two outer lateral surfaces 40A of the four outer lateral surfaces 40A, and the covering layer 12 is not disposed on the other two outer lateral surfaces 40A. By disposing the covering layer 12 only on the desired outer lateral surface 40A among the outer lateral surfaces 40A in this way, for example, the light emitted from the light-emitting element 24 can be made to be less likely to leak out from the outer lateral surface 40A on which the covering layer 12 is disposed.

### Light-Emitting Device Manufacturing Method 2

A light-emitting device manufacturing method 2 includes the following steps:
(3-1) Step of preparing the substrate including the base, the covering layer disposed on the lateral surface of the base, and the support member supporting the base
(3-2) Step of disposing the light-emitting element on the base

In the steps described above, the step (3-1) is similar to the step (1-1) in the first embodiment, and the step (3-2) is similar to the step (2-2) in the light-emitting device manufacturing method 1. Thus, the description of these steps is omitted.

What is claimed is:

1. A method for manufacturing a substrate, comprising:
preparing a substrate intermediate including
a plurality of bases each having an upper surface and an outer lateral surface continuous with the upper surface, and
a support member supporting the bases such that the outer lateral surfaces of the bases are spaced apart from each other;
preparing a plate-shaped member defining a plurality of openings;
disposing the plate-shaped member on the support member such that at least a portion of an inner lateral surface of each of the openings of the plate-shaped member and at least a portion of the outer lateral surface of a corresponding one of the bases face each other via a gap;
supplying a resin member to the gap such that the resin member covers the outer lateral surface of each of the bases; and
curing the resin member to form a covering layer covering the outer lateral surface of each of the bases.

2. The method for manufacturing a substrate, according to claim 1, wherein
the preparing of the plate-shaped member includes defining the openings such that the inner lateral surface defining each of the openings includes a first inner lateral surface and a second inner lateral surface located on an outer side relative to the first inner lateral surface, and
the supplying of the resin member includes disposing the resin member in the gap between the first inner lateral surface of each of the openings and the outer lateral surface of the corresponding one of the bases.

3. The method for manufacturing a substrate, according to claim 1, wherein
the preparing of the plate-shaped member includes preparing the plate-shaped member that further defines dents with each of the dents being continuous with a corresponding one of the openings on an upper surface of the plate-shaped member, and
the supplying of the resin member includes disposing the resin member in the gap via the dent.

4. The method for manufacturing a substrate, according to claim 1, wherein
the supplying of the resin member includes supplying the resin member so that a brightness of the covering layer is lower than a brightness of each of the bases after the curing of the resin member.

5. The method for manufacturing a substrate, according to claim 1, wherein
the preparing of the substrate intermediate includes preparing the substrate intermediate in which the support member is a lead frame, and each of the bases is a molded body containing a resin as a main component.

6. The method for manufacturing a substrate, according to claim 5, wherein
the preparing of the substrate intermediate includes preparing the substrate intermediate in which each of the bases further includes a light-shielding layer disposed on an upper surface of the molded body.

7. The method for manufacturing a substrate, according to claim 6, wherein
the supplying of the resin member includes disposing the resin member such that the resin member covers the light-shielding layer.

8. The method for manufacturing a substrate according to claim 1, further comprising
removing the plate-shaped member from the substrate intermediate before or after the curing of the resin member.

9. The method for manufacturing a substate according to claim 2, wherein
the preparing of the plate-shaped member includes defining the openings such that the first inner lateral surface of each of the openings defines a lateral surface groove spaced apart from an upper edge and a lower edge of the first inner lateral surface.

10. The method for manufacturing a substate according to claim 1, wherein
the preparing of the plate-shaped member includes defining the openings such that a part of the plate-shaped member overlaps a part of a corresponding one of the bases in a plan view.

11. The method for manufacturing a substrate, according to claim 1, wherein
the preparing of the substrate intermediate includes preparing the substrate intermediate in which the support member has an adhesive surface on which the bases are disposed.

12. A method for manufacturing a light-emitting device, comprising:
preparing an intermediate member including
a plurality of light-emitting device intermediates each including a plurality of bases each having an upper surface and an outer lateral surface continuous with the upper surface, and a plurality of light-emitting elements held on the bases, and
a support member supporting the light-emitting device intermediates such that the outer lateral surfaces of the bases are spaced apart from each other;
preparing a plate-shaped member defining a plurality of openings;
disposing the plate-shaped member on the support member such that at least a portion of an inner lateral surface of each of the openings of the plate-shaped member and at least a portion of the outer lateral surface of a corresponding one of the bases face each other via a gap;
supplying a resin member to the gap such that the resin member covers the outer lateral surface of each of the bases; and
curing the resin member to form a covering layer covering the outer lateral surface of each of the bases.

13. The method for manufacturing a light-emitting device, according to claim 12, wherein
the preparing of the intermediate member includes preparing the intermediate member so that the light-emitting elements include a blue light-emitting element, a green light-emitting element, and a red light-emitting element.
